(19) United States
(12) Patent Application Publication
(10) Pub. No.: US 2009/0178273 A1
(43) Pub. Date: Jul. 16, 2009

(54) Method of making circuitized assembly including a plurality of circuitized substrates

(75) Inventor: John M. Lauffer, Waverly, NY (US)

Correspondence Address: LAWRENCE R. FRALEY;Hinman, Howard & Kattell, LLP, 700 Security Mutual Building, 80 Exchange Street, Binghamton, NY, 13902-5250, US

(73) Assignee: Endicott Interconnect Technologies, Inc., Endicott, NY (US)

(21) Appl. No.: 12/007,704

(22) Filed: Jan. 15, 2008

(51) Int. Cl. H05K 3/36

(52) U.S. Cl. 29/830

(57) ABSTRACT

A method of forming a circuitized substrate assembly in which at least two adjacent and contiguous circuitized substrates have at least one, and possibly a second, circuitized substrate positioned thereon and bonded thereto to form a combined circuitized substrate assembly. The substrates each include at least one conductive thru-hole therein such that the bonding will cause respective pairs (at least one pair if only three substrates are used) of the thru-holes to align and become electrically coupled, thereby forming at least one and preferably more electrical circuit paths through the combined assembly to electrically couple electrical components positioned on selected ones of the circuitized substrates.

### TECHNICAL FIELD

This invention relates to circuitized substrates and particularly multilayered printed circuit boards (also known as printed wiring boards) and to processes for the manufacture of same.

### BACKGROUND OF THE INVENTION

As is known, multilayer printed circuit boards (PCBs) permit the formation of multiple circuits in a minimum volume or space. These typically comprise a stack of layers of signal, ground and/or power planes (lines) separated from each other by a layer of dielectric material. The lines are often in electrical contact with each other by plated holes passing through the dielectric layers. The plated holes are often referred to as “vias”, and may include what are referred to also as “buried vias” or “blind vias.” “Vias” which extend through the entire board thickness are also referred to as plated through holes (PTHs).

Known processes for fabricating PCBs typically comprise fabrication of separate inner-layer circuit structures, which are formed by coating a photosensitive layer or film (sometimes referred to as photo-resist or, more simply, resist) over a copper layer of a copper-clad inner-layer base (dielectric) material. The photosensitive coating is imaged, developed and etched to form conductor lines. After etching, the photosensitive film is stripped from the copper leaving the circuit pattern on the surface of the inner-layer base material. This well known process is also known as photolithographic processing.

After formation of these individual inner-layer circuits, a multilayered stack is formed by preparing a lay-up of the inner-layer structures, ground planes, power planes, etc., typically separated from each other by a dielectric pre-preg layer typically comprising a layer of glass cloth impregnated with partially cured material, typically a B-stage epoxy resin. The top and bottom outer layers of the stack often comprise circuitry thereon. The stack is laminated to form a monolithic structure using heat and pressure to fully cure the B-stage resin. The stack so formed thus typically has copper cladding on both of its exterior surfaces. Exterior circuit layers are formed in the copper cladding using procedures similar to the procedures used to form the inner-layer circuit structures. That is, a photosensitive film is applied to the copper cladding. The coating is exposed to patterned activating radiation and developed. An etchant is then used to remove copper bared by the development of the photosensitive film. Finally, the remaining photosensitive film is removed to provide the exterior circuit layers.

Conductive “vias” (or “interconnects” as also referred to in the art) are used to electrically connect individual circuit layers within a stack (now a PCB) to each other and to the outer surfaces and typically pass through all or a portion of the PCB (see the definition below). Most “vias” are generally formed as part of the formation of the circuit inner-layer sub-composite structures by drilling holes through the structures at appropriate locations. Such drilling may be achieved using mechanical drills or lasers. Following several pre-treatment steps, the walls of such “vias” are usually catalyzed by contact with a plating catalyst and metallized, typically by contact with an electroless or electrolytic copper plating solution to form conductive pathways between designated circuit layers. As stated, these inner-layer structures are then precisely aligned and bonded, usually using conventional lamination processes in which elevated pressures and temperatures are utilized.

Following the formation of such a stacked structure (now a multilayered PCB), semiconductor chips and other electrical components are often mounted at appropriate locations on the exterior circuit layers, typically using solder mount pads to bond the components. The components are usually in electrical contact with the inner circuit (conductive) layers using the “vias.” The pads are typically formed by coating an organic solder mask coating over selected parts of the exterior circuit layers. The solder mask material, many of which are known, may be applied by screen coating a liquid coating over the exterior circuit layer using a screen having openings defining areas where solder mount pads are to be formed. Alternatively, a photo-imageable solder mask may be coated onto the board's outer surfaces and exposed and developed to yield an array of openings defining the pads. The openings are then coated with solder using procedures known to the art such as wave soldering.

The following patents describe various PCBs of various structures, including where two or more “sub-structures” or “sub-composites” or “sub-assemblies” are combined. Other terms, such as circuitized substrate assemblies, circuitized substrates, composites, etc. may be used in the following and also in the art, and are understandably often interchangeable with respect to defining the various elements of such products. To avoid confusion, the definitions intended for the instant invention are provided herein-below. The citation of these documents is not an admission that any is prior art to the presently claimed invention.

In U.S. Pat. No. 5,419,806, there is described a method for producing a three-dimensional circuit apparatus, wherein substrates that are arranged above one another are firmly joined to one another by depressions in the adjoining surfaces of the neighboring substrates. The depressions are filled with a mixture of two metal constituents, one being a liquid and the other being a solid and the solid constituent dissolves in the liquid constituent, which leads to the hardening of the mixture, and firmly joins the depressions to one another due to the hardening of the mixture. In addition, detached components are arranged on prepared substrate wafers and are firmly joined thereto.

In U.S. Pat. No. 5,583,321, there are described multilayer circuit assemblies made by stacking circuit panels having contacts on their top surfaces, through conductors extending between top and bottom surfaces and terminals connected to the bottom end of each through conductor. The terminals and contacts are arranged so that when the panels are stacked the terminals on the bottom of one panel are in alignment with the contacts on the top surface of the immediately underlying panel. The panels are selectively treated on their top and/or bottom surfaces so as to selectively disconnect or connect each contact to a terminal on the bottom surface of the same panel. For example, the top surface of the panel may be selectively etched to disconnect a contact from one through conductor and hence from the associated terminal. The aligned terminals and contacts are non-selectively connected to one another at each interface so that wherever a terminal and contact on adjacent panels are aligned with one another there are connected to one another. This forms composite vertical conductors extending through a plurality of the panels. The selective treatment of the panel top and bottom surfaces provides selective interruptions in the vertical conductors. A circuit panel precursor having the through conductors and methods of making the same are also provided.

In U.S. Pat. No. 5,822,856, there are described circuit boards manufactured by forming a substrate with a dielectric surface, laminating a metal foil and a peelable film to the substrate, and forming holes in the substrate through the peelable film and foil. A filler material with an organic base may be filled with electro-conductive particles or dielectric thermo-conductive particles. The filler material is laminated onto the peelable film with sufficient heat and pressure to force the filler material to fill the holes. For thermo-conductive filler the holes are filled sufficient for electrical connection through the holes. The filler material is abraded to the level of the foil and is then copper plated. The copper is patterned to form a wiring layer. A permanent photo-resist layer is formed over the wiring layer, and via holes are then formed through the photo-imageable dielectric over pads and conductors of the wiring layer. Holes are formed through the substrate and the photo-imageable dielectric, walls of the via holes, and walls of the through holes are copper plated. The copper plating on the photo-imageable dielectric is patterned to form an exterior wiring layer. Components and/or pins are attached to the surface of the circuitized substrate with solder joints to form a high density circuit board assembly.

In U.S. Pat. No. 5,876,842, there is described a modular structure for providing electrical interconnections that achieve greatly increased wiring density by forming vias and wiring patterns by chemical (e.g. lithographic) processes rather than by mechanical processes such as punching of vias and screening patterns of conductive paste. A basic module is a power core comprising an apertured metallic foil with an insulator applied to surfaces thereof, extending through at least one aperture and exposing the metallic foil in at least one aperture. The foil in the power core provides stiffness to facilitate subsequent handling and electrical shielding between conductive layers as well as a potential power connection. Via connections of increased conductivity and robustness are formed by plating the interior of vias after lamination of a desired combination of power cores and signal cores. Vias remain unfilled until after lamination and are available to facilitate optical alignment of composite layers including signal cores, power cores and laminated combinations thereof.

In U.S. Pat. No. 5,902,118, there is described a method of producing a three-dimensional circuit arrangement. Two substrates which have components in the region of their boundary surfaces which touch one another are stacked one on top of the other. The substrates are firmly connected to one another via these boundary surfaces. One of the substrates can subsequently be thinned from the rear side and can be provided with rear-side contacts, the other substrate acting as a stabilizing supporting plate.

In U.S. Pat. No. 5,956,843, there is described a multilayered printed wiring board which includes two or more layers each having a via hole therein, these holes aligned vertically above one another to minimize board real estate while assuring an effective circuit path between respective points on the two layers. One or both via holes can be filled with either an electrically conductive material (e.g., copper paste) or a nonconductive material (e.g., resin).

In U.S. Pat. No. 6,026,564, there is described a process of making a multilayer printed wiring board assembly. The process includes the steps of providing a first and a second substrate made of a dielectric material; depositing a first wiring pattern on the first substrate and a second wiring pattern on the second substrate with a conductive material; depositing a dielectric material on the first and second wiring patterns and defining a via connecting zone on the first and the second wiring pattern for communicating signals between the first and the second wiring pattern by exposing a selective portion of the first and second wiring patterns; depositing a conductive bonding material on the via connecting zone of one of the first and the second wiring pattern; arranging the first and the second substrate in sandwiched juxtaposition such that the via connecting zones of the first and the second wiring pattern are opposite each other and in substantial alignment with each other so that the conductive bonding material deposited on the one of the via connecting zones contacts another one of the via connecting zones; and curing the deposited bonding material thereby forming a conductive joint connecting the first and the second via connecting zones.

In U.S. Pat. No. 6,054,761, there are described printed circuit substrates and electrical assemblies including a conductive composition. The printed circuit substrate and the electrical assembly embodiments comprise a first conducting region and a second conducting region. A dielectric layer is disposed between the first and second conducting regions. An aperture is disposed in the dielectric layer and a via structure including the conductive composition is disposed in the aperture. The conductive composition is preferably in a cured state and electrically communicates with the first and second conducting regions.

In U.S. Pat. No. 6,388,204, there is described a laminate circuit structure assembly that comprises at least two modularized circuitized plane subassemblies; a joining layer located between each of the subassemblies and wherein the subassemblies and joining layer are bonded together with a cured dielectric from a bondable, curable dielectric. The subassemblies and joining layer are electrically interconnected with bondable electrically conductive material. The joining layer comprises dielectric layers disposed about an internal electrically conductive layer. The electrically conductive layer has a via and the dielectric layers each have a via of smaller diameter than the vias in the electrically conductive layer and are aligned with the vias in the electrically conductive layer. The vias are filled with electrically bondable electrically conductive material for providing electrical contact between the subassemblies.

In U.S. Pat. No. 6,479,093, there is described a laminate circuit structure assembly that comprises at least two modularized circuitized plane subassemblies; a joining layer located between each of the subassemblies and wherein the subassemblies and joining layer are bonded together with a cured dielectric from a bondable, curable dielectric. The subassemblies and joining layer are electrically interconnected with bondable electrically conductive material. The joining layer comprises dielectric layers disposed about an internal electrically conductive layer. The electrically conductive layer has a via and the dielectric layers each have a via of smaller diameter than the vias in the electrically conductive layer and are aligned with the vias in the electrically conductive layer. The vias are filled with electrically bondable electrically conductive material for providing electrical contact between the subassemblies.

In U.S. Pat. No. 6,809,269, there is defined a circuitized substrate assembly and method for making same wherein the assembly includes individual circuitized substrates bonded together. The substrates each include at least one opening, only one of which is substantially filled with a conductive paste prior to bonding. Once bonded, the paste is also partially located within the other opening to provide an effective electrical connection therewith.

In U.S. Pat. No. 6,974,333, there is described a high-density connection of multiple circuit boards having overlapping ends arranged in a stack. The metal traces on the stacked circuit boards are electrically connected by contact of the ends of the traces, which ends may be pads. The stacked circuit boards can be clamped, soldered or bonded together. Multiple circuit boards may be connected to a single circuit board. In one embodiment, double-sided circuit boards are stacked so that a first circuit board connects to a second circuit board through a third circuit board disposed intermediate the first and second circuit boards. The circuit boards may be flexible or rigid.

In U.S. Pat. No. 7,047,630, there is defined a circuitized substrate assembly and method for making same wherein the assembly includes individual circuitized substrates bonded together. The substrates each include at least one opening, only one of which is substantially filled with a conductive paste prior to bonding. Once bonded, the paste is also partially located within the other opening to provide an effective electrical connection therewith.

In U.S. Pat. No. 7,163,847, there is defined a method of making a circuitized substrate in which the substrate's commoning bar, used during the plating of the circuitry on the substrate, is terminated from the various conductors using a laser. In a preferred embodiment, the laser acts through a dielectric layer (soldermask) which is applied over the circuitry, including the commoning bar and connected parts. The laser may also be used to expose selected ones of the circuit's other parts, including various pads used to accommodate a wirebond (from a chip) and also solder balls for eventual placement of the substrate on a larger circuit board.

In U.S. Pat. No. 7,211,289, there is defined a method of making a printed circuit board in which conductive thru-holes are formed within two dielectric layers of the board's structure so as to connect designated conductive layers. One hole connects two adjacent layers and the other connects two adjacent layers, including one of the conductive layers connected by the other hole. It is also possible to connect all three conductive layers using one or more holes. The resulting holes may be filled, e.g., with metal plating, or conductive or non-conductive paste. In the case of the latter, it is also possible to provide a top covering conductive layer over the paste, e.g., to serve as a pad or the like on the board's external surface.

The above-referenced U.S. Pat. Nos. 6,809,269, 7,047,630, 7,163,847 and 7,211,289 are assigned to the same Assignee as the present invention, Endicott Interconnect Technologies, Inc.

Demands on PCBs have increased significantly over the past few years. For example, boards for mainframe computers and other similar products may have as many as thirty-six layers of circuitry or more, with the complete stack having a thickness of 0.250 inch or even more. As these demands increase further, one possible solution is to provide boards of much great widths (and, possibly, lengths) than those known today. Unfortunately, many PCB fabrication shops are limited by their equipment's capabilities such that PCB widths of only about twenty-four to thirty inches are possible. The present invention defines a solution to meet these increased demands, by teaching a method of making a circuit board assembly in which three or more circuit boards (circuitized substrates) are aligned and bonded with appropriate means of electrically interconnecting same. As taught herein, the invention is able to accomplish this by precisely aligning the circuitized substrates (defined below) and bonding these such that precise electrical connections are formed. As further taught, the invention is able to do so such that components mounted on the assembly are assured effective coupling between each other and other internal circuitry of the large assembly.

It is believed that such an invention will represent a significant advancement in the art.

### OBJECTS AND SUMMARY OF THE INVENTION

It is a primary object of the invention to enhance the art of circuitized substrates, and particularly the art of circuitized substrate assemblies (as defined below).

It is another object to provide a new and unique method of making a circuitized substrate assembly which is adaptable to current manufacturing procedures, to thereby result in a product of relatively low cost.

According to one aspect of the invention, there is provided a method of making a circuitized substrate assembly comprising providing first and second circuitized substrates, each having a first side and including at least one conductive thru-hole therein, orienting the first and second circuitized substrates in a substantially planar orientation wherein the first sides are substantially contiguous, positioning a third circuitized substrate having first and second conductive thru-holes therein onto both the first and second circuitized substrates such that the first conductive thru-hole of this third circuitized substrate is aligned with the conductive thru-hole of the first circuitized substrate and the second conductive thru-hole of the third circuitized substrate is aligned with the conductive thru-hole of the second circuitized substrate, and bonding the three circuitized substrates together such that the first conductive thru-hole of the third circuitized substrate is electrically coupled to the conductive thru-hole of the first circuitized substrate and the second conductive thru-hole of the third circuitized substrate is electrically coupled to the conductive thru-hole of the second circuitized substrate, the bonded first, second and third circuitized substrates forming a circuitized substrate assembly.

According to another aspect of the invention, there is provided a method of making a circuitized substrate assembly comprising providing first and second circuitized substrates, the first circuitized substrate having a first side and including at least one conductive thru-hole therein, the second circuitized substrate having a first side and including at least one conductive thru-hole therein, orienting the first and second circuitized substrates in a substantially planar orientation wherein the first side of the first circuitized substrate is positioned substantially contiguous to the first side of the second circuitized substrate, providing third and fourth circuitized substrates, the third circuitized substrate having a first side and including at least one conductive thru-hole therein, the fourth circuitized substrate having a first side and including at least one conductive thru-hole therein, positioning these third and fourth circuitized substrates on the first and second circuitized substrates wherein the first side of this third circuitized substrate is positioned substantially contiguous to the first side of the fourth circuitized substrate and the conductive thru-hole of the third circuitized substrate is aligned with the conductive thru-hole of the first circuitized substrate and the conductive thru-hole of said fourth circuitized substrate is aligned with the conductive thru-hole of the second circuitized substrate, and bonding the first, second, third and fourth circuitized substrates together such that the conductive thru-hole of the third circuitized substrate is electrically coupled to the conductive thru-hole of the first circuitized substrate and the conductive thru-hole of the fourth circuitized substrate is electrically coupled to the conductive thru-hole of the second circuitized substrate. These bonded first, second, third and fourth circuitized substrates form a circuitized substrate assembly.

### BRIEF DESCRIPTION OF THE DRAWINGS

FIG. 1 is a perspective view, on a much reduced scale, showing a circuitized substrate assembly made in accordance with one embodiment of the teachings of this invention;

FIG. 2 is a side elevational view, in section and on a much enlarged scale over the view of FIG. 1, illustrating a circuitized substrate assembly and more particularly examples of the internal electrical couplings possible for this invention, when made using the teachings herein; and

FIGS. 3-5 are side elevational views, on a much reduced scale over the view of FIG. 2, illustrating examples of the various electrical circuit path schemes possible using the teachings of this invention, it being understood that there are several possible permutations and combinations of same.

### BEST MODE FOR CARRYING OUT THE INVENTION

For a better understanding of the present invention, together with other and further objects, advantages and capabilities thereof, reference is made to the following disclosure and appended claims in connection with the above-described drawings. It is understood that like numerals will be used to indicate like elements from drawing figure to drawing figure.

By the term “circuitized substrate” as used herein is meant to include substrates having at least one (and preferably more) dielectric layer(s) and at least one (and preferably more) metal electrically conductive layer(s). Examples of dielectric materials for the dielectric layers include fiberglass-reinforced epoxy resins (some referred to as “FR-4” dielectric materials in the art), polytetrafluoroethylene (Teflon), polyimides, polyamides, cyanate resins, photo-imageable materials, and other like materials. Examples of metal materials for use as the electrically conductive layers (e.g., power, signal and/or ground layers) include copper and copper alloys, but may be of (or include with the copper or copper alloy) additional metals (e.g., nickel, aluminum, etc.) or alloys thereof. If the dielectric materials for the structure are of a photo-imageable material, it is photo-imaged or photo-patterned, and developed to reveal the desired circuit pattern, including the desired opening(s) as defined herein, if required. The dielectric material may be curtain-coated or screen-applied, or it may be applied as dry film. Final cure of the photo-imageable material provides a toughened base of dielectric on which the desired electrical circuitry is formed. It is believed that the teachings of the instant invention are also applicable to what are known as “flex” circuits (which use dielectric materials such as polyimide) and those which use ceramic or other non-polymer type dielectric layers, one example of the latter being what are referred to as multi-layered ceramic (MLC) modules adapted for having one or more semiconductor chips mounted thereon.

By the term “circuitized substrate assembly” is meant an assembly comprised of three or more circuitized substrates bonded together.

By the term “electrical component” as used herein is meant components such as semiconductor chips and the like which are adapted for being positioned on the external conductive surfaces of circuitized substrates (as well as circuitized substrate assemblies) and electrically coupled to the substrate (or assembly) for passing electrical signals from the component into the substrate whereupon such signals may be passed on to other components, if desired, including those mounted also on the substrate (or assembly), as well as other components such as those of a larger electrical system in which the substrate (or assembly) is positioned.

By the term “conductive thru-hole” as used herein is meant to include the aforementioned “blind vias” which are electrically conductive openings typically from one surface of a circuitized substrate to a predetermined distance therein, the also aforementioned “buried vias” which are electrically conductive openings located internally of the substrate and are typically formed within one or more internal layers prior to bonding (e.g., lamination) thereof to other layers to form the ultimate structure, and the aforementioned electrically conductive PTHs. All of these various openings form electrical paths through the substrate and often include one or more conductive layers, e.g., plated copper, on the internal walls thereof. Such openings may also include a quantity of conductive paste or, still further, the paste may be in addition to the plated metal on the internal walls. These openings in the substrate are formed typically using mechanical drilling or laser ablation, following which the plating and/or conductive paste are added.

By the term “information handling system” as used herein shall mean any instrumentality or aggregate of instrumentalities primarily designed to compute, classify, process, transmit, receive, retrieve, originate, switch, store, display, manifest, measure, detect, record, reproduce, handle or utilize any form of information, intelligence or data for business, scientific, control or other purposes. Examples include personal computers and larger processors such as servers, mainframes, etc.

In FIG. 1, there is shown one example of a circuitized substrate assembly 11 of the invention. Assembly 11 is shown to comprise five circuitized substrates (e.g., PCBs) 13, 15, 17, 19 and 21 which are bonded together in such a manner so as to form assembly 11. Although five substrates are shown, it is understood that in accordance with the broadest aspects of this invention, only three such substrates are required. The assembly as shown is able to be formed of a width (W3) which is greater than the maximum widths mentioned which many conventional PCB manufacturing apparatus are able to produce single PCBs. In the FIG. 1 example, the combined width W3 may be from about thirty inches to about sixty inches, or similar to the combined, corresponding widths (W1 and W2) of the top two adjacent substrates 19 and 21. A width as great as sixty inches (five feet) illustrates an example of how large a combined board product which may be produced using the new and unique teachings herein. Boards of such widths are becoming more in demand for various specialized applications, e.g., defense. In the FIG. 1 embodiment, W3 is also similar to the combined widths of the three underlying substrates 13, 15 and 17. These widths are representative only and not limiting of this invention. As mentioned above, the combining of at least two adjacent substrates with at least one additional substrate enables a combined assembly capable of having such greater widths. In the case of only three substrates, the upper single substrate may not have a width equal to the combined widths of the underlying two, but be positioned offset on these two, leaving a single substrate projecting from above the plane of the combined two.

The embodiment of FIG. 1, or at least an embodiment in which four or more substrates are used, is preferred because it enables a combined assembly 11 of uniform thickness across the entire width thereof. It also enables the provision of more circuitry to thereby enhance the functional capabilities of the final product. Again, however, the invention is not limited to assemblies having four or more substrates.

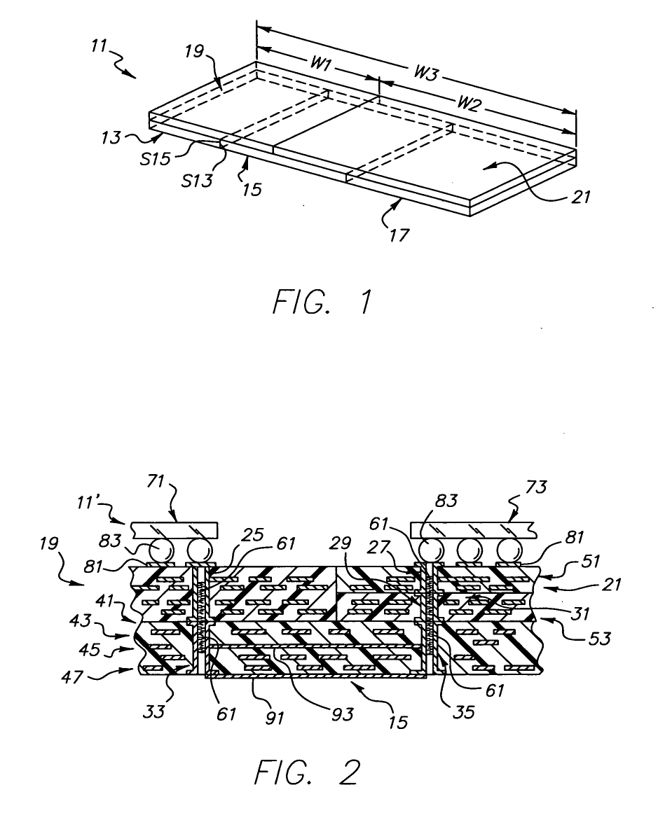

Each circuitized substrate (only three, 15, 19 and 21 being shown in FIG. 2) includes at least one (and preferably several) conductive thru-holes therein. In FIG. 2, substrate 19 includes thru-hole 25, substrate 21 includes two aligned thru-holes 27 and 29 (which form one continuous thru-hole 31), and substrate 15 includes two thru-holes 33 and 35. Significantly, the thru-holes in substrates 15 and 19 extend through the entire substrate thickness. Such thru-holes may be formed when each substrate is formed using conventional bonding (lamination) of the designated number of conductive and dielectric layers. For example, substrate 15 is shown to include four internal conductive layers 41, 43, 45 and 47, with known dielectric layers positioned there-between. Additionally, substrate 15 (and 19) include additional dielectric layers on the outer portion of the conductive layers and, as explained above, may also include conductive layers on the exterior surface(s) thereof. Such constructions are known in the art and further description (except as needed below to define the operation of the invention) is not considered necessary. In contrast to substrates 15 and 19, substrate 21 may be formed of two (or more) sub-composite substrates 51 and 53, each being formed of multiple conductive and dielectric layers bonded together. A thru-hole (i.e., 27, in substrate 51) is formed in each and the two sub-composites aligned and bonded to form a single, contiguous conductive thru-hole 31. This formed substrate 21 is now capable of being aligned with the other substrates in accordance with the teachings herein.

Significantly, one method of bonding the substrates (and, in the case of substrate 51, the two sub-composite substrates 51 and 53) is to use what may be referred to as “z-interconnect” connections, developed by the Assignee of this invention, Endicott Interconnect Technologies, Inc., for bonding aligned substrates. Examples of this process are defined in the above-identified U.S. Pat. Nos. 6,809,269 and 7,047,630, in addition to other U.S. patents issued to this Assignee. The teachings of U.S. Pat. Nos. 6,809,269 and 7,047,630 are incorporated herein by reference. Such “z-interconnect” couplings are able to securely bond the substrates in an aligned (vertical) manner while, significantly, forming effective electrical connections between also aligned conductive thru-holes therein. Substrates 15, 19 and 21, as well as substrates 13 and 17, are bonded using this procedure. More specifically, lower substrates 13, 15 and 17 are aligned in a planar manner (e.g., on a base) in a side-by-side orientation such that adjacent sides (i.e., S13, S15) of two adjacent substrates are contiguous. (Thus, the side of substrate 17 is contiguous to the adjacent side of substrate 15, this side being opposite to side S15.) Lateral bonding of the three substrates at these contiguous sides may be accomplished using a suitable bonding cement (or adhesive), such as Scotch-Weld DP-460 EG, available from 3M Electronics Markets Materials Division, having a business location at 900 Bush Avenue, St. Paul, Minn. Other cements and adhesives may be used for this purpose and the invention is not limited to that cited.

With the three adjacent (and contiguous) substrates 13, 15 and 17 so oriented, the next step involves positioning the upper two substrates 19 and 21 thereon. Substrates 19 and 21 are also preferably positioned contiguously, with adjacent sides mating against each other. Cement (or adhesive) is also preferably used at this point to bond the two in a lateral manner, as shown. Alignment of the substrates is preferably accomplished using mechanical pinning tools on a fixture plate, in order to assure the precise alignment (especially between the conductive thru-holes of the substrates) necessary. With the five substrates so oriented, the next step is to form a bond between the upper pair and the lower substrates. As mentioned, this is accomplished using the Assignee's “z-interconnect” process in which conductive paste 61 is positioned within selected ones of the thru-holes, the thru-holes (and of course the substrates including same) are aligned (using the above procedure) and then all are bonded. The preferred bonding method involves using lamination processing and, in the example shown in FIG. 1, this process may be conducted at a temperature within the range of from about 180 degrees C. (Celsius) to about 220 degrees C. and at a pressure within the range of from about 300 pounds per square inch (PSI) to about 1100 PSI. These temperatures and pressures are not limiting of this invention as it is possible to use others, depending on such factors as substrate thickness, dielectric materials, etc. The result of this pressurized and high temperature bonding is that the paste 61 extends within aligned thru-holes (as shown) to assure and enhanced electrical path through the substrate over that provided by a thru-hole formed of only thin plating material on the internal dielectric sidewalls of the formed opening through/within the substrate. Attention is again directed to U.S. Pat. Nos. 6,809,269 and 7,047,630 of the Assignee.

Another embodiment of the invention utilizes an alternative sequence of combining the substrates. With reference to FIG. 1, substrates 19 and 13 may be bonded together in a first lamination step and substrates 21 and 17 may be bonded together in a second lamination step. A third lamination step would be used to bond the substrate “subassemblies” 19-13 and 21-17 to the lower, interim substrate 15. The above lamination pressures and temperatures may be used. The particular advantage of this embodiment of the invention is that the substrates can all be electrically tested individually prior to any bonding, and then the laminated substrates can be electrically tested after each bonding step. This allows electrically defective substrates or combined substrates to be discarded at a lower cost level.

In FIG. 2, assembly 11′ is shown to further include a pair of electrical components 71 and 73 positioned on and electrically coupled to a respective upper surface of the two contiguous substrates 19 and 21. Components 71 and 73 may be semiconductor chips, chip carriers (packages with one or more semiconductor chips therein) or other devices known in the art. In a preferred embodiment, components 71 and 73 are chips and bonded to corresponding conductor pads 81 on the upper surfaces as shown using solder ball 83 connections. One form of such connection is known in the art as “C4” coupling, standing for controlled collapse chip connection in which solder balls 83 are oriented in position and re-flowed at elevated temperatures to accomplish the desired couplings to the respective pads 81. Other conventional forms of connecting components on substrates such as PCBs are also possible, including wire-bonding.

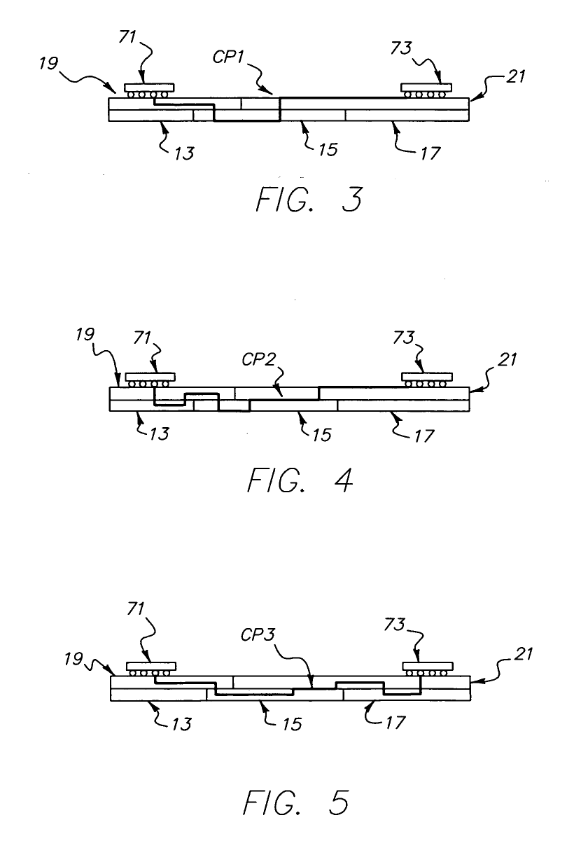

In accordance with the teachings herein, the present invention is able to provide effective electrical coupling between the two components 71 and 73 (as well as others which might also be so positioned, albeit at other locations spaced from the two shown) by providing at least one (and possibly several) electrical circuit path(s) through the bonded assembly 11′. Examples of such paths are shown in FIGS. 3, 4 and 5. In the specific example of FIG. 2, a path is formed from component 71 solder ball 83 (to the right) down through the aligned thru-holes 61 in substrates 15 and 19, along an outer circuit line 91 on the undersurface of substrate 15, up through the aligned thru-holes in substrate 15 and 21 to the respective solder ball 83 (to the left) on component 73. This is not limiting of the several permutations and combinations of circuit paths attainable using the teachings herein. It is also possible, for example, to form part of the circuit path(s) using internal conductor planes (e.g., one or more signal lines) within the various substrates. One such example is signal line 93 which couples the thru-holes in substrate 15. That is, the internal conductor material (plating and/or paste) of each hole is electrically coupled to this signal line as part of the formation of substrate 15. Such connections are known in the art and further description is not deemed necessary. FIG. 2 thus illustrates two circuit paths between components 71 and 73. As mentioned, many others are possible.

It is also understood that the present invention is able to provide interconnections between all of the contact sites of one component to all on the other, or to less than all, depending on the operational requirements for assembly 11′. The invention is thus not limited to connecting one conductor of each to a respective one on the other. Further, it is also possible to provide other than a signal electrical path for one or more of the component's conductors. For example, it is possible that signal line 93 instead be a solid plane so as to provide a power or ground function. Power or ground planes are known in the art for use in PCBs. Other possibilities are well within the capabilities of those with ordinary skill in the art.

As stated, FIGS. 3-5 illustrate further possible examples of circuit paths attainable using the teachings herein. Internal (within the substrate) signal paths, power or ground planes, conductive thru-holes, conductive paste and various other structures are not shown in FIGS. 3-5 for ease of explanation. When such a structure is mentioned, it is understood to be present, albeit not shown, where noted. As understood, examples of such structures are well represented in FIG. 2. In FIG. 3, circuit path CP1 from component 71 utilizes a thru-hole immediately beneath the component, a lateral signal path which moves horizontally to a second thru-hole also in the same substrate (19), which in turn is coupled to a mating thru-hole in the lower substrate 15 (which extends through the substrate's complete thickness), along an outer signal line on the lower substrate's external surface, upwards into a second thru-hole in substrate 15 to a mating thru-hole in the upper substrate 21 and then across a signal line on the upper substrate's external surface, where it ends at a pad on which one of the solder balls of component 73 is mounted. In this embodiment, substrates 13 and 17 are omitted, thus giving the reader an appreciation for the lower number of such substrates which might be used to provide this circuit path. It is also understood that many additional circuit paths may be provided in addition to CP1, depending on the number required.

In FIG. 4, circuit path CP2 is somewhat more complex than CP1, running from component 71 down through a thru-hole in substrate 19 to a mating thru-hole in the under substrate 13, where it then moves laterally through the interior of substrate 13 to a second thru-hole in this same substrate where it moves upwardly to mate with a second thru-hole in upper substrate 19, laterally across substrate 19 to yet a third thru-hole in this same substrate and then downwardly to pass through a thru-hole in substrate 15 until it reaches the external surface of substrate 15. The circuit path passes along this outer, lower external surface until it reaches a second thru-hole in substrate 15 and then passes along the upper, external surface of this substrate. It then engages a thru-hole (via a land thereabout) in substrate 21 and passes entirely up through substrate 21. As with CP1, it now passes along the upper surface of substrate 21 until it reaches a pad having a solder ball from component 73 thereon. In this embodiment, it is not necessary to utilize substrate 17, although it is fully understood that said substrate could be utilized if needed (as is the case with substrates 13 and 17 in the FIG. 3 embodiment). This embodiment illustrates the adaptability of the invention to substrates with a large number of thru-holes therein, as it uses eight thru-holes, compared to only five in FIG. 3. These numbers are illustrative only, of course, and not limiting of the invention but provided to better emphasize that the invention is adaptable to a wide range of thru-holes in such a substrate product.

In FIG. 5, circuit path CP3 from component 71 utilizes a thru-hole immediately beneath the component, a lateral signal path which moves horizontally to a second thru-hole also in the same substrate (19), which in turn is coupled to a mating thru-hole in the lower substrate 15, but, unlike the FIG. 3 embodiment, only passes partially into the lower substrate and then moves laterally to a second thru-hole in this same substrate and upwardly therethrough, where it passes along the substrate's upper surface to a partial depth thru-hole in upper substrate 21. It then moves laterally through substrate 21 to a second thru-hole in this substrate and then downwardly to mate with a thru-hole in lower substrate 17. It moves laterally to a second thru-hole in substrate and then directly upward (into a vertical thru-hole in substrate 21) to a pad of component 73. This embodiment represents the relative ease at which the invention is able to utilize several internal and external signal (or power or ground) paths of the various substrates.

Thus there has been shown and described a method of making a circuitized substrate assembly which utilizes a plurality of substrates which are bonded together in such a manner so as to provide an assembly having a larger overall width than possible for many conventional substrates. This greater width assembly is able to carry more circuit paths and both external and internal components, thus providing it with greater operational capabilities than conventional substrates of lesser widths. Significantly, the bonded structure as defined herein is attainable using PCB manufacturing processes (e.g., thru-hole, internal and external circuit line and/or plane formation) known in the art but in a new and unique manner unobvious to those of ordinary skill in the art. The method is thus able to be accomplished at relatively low costs.

Circuitized substrate assemblies as defined herein may be utilized in many electronic structures, with examples being information handling systems such as personal computers, servers and mainframes. These assemblies may, for example, form the “motherboard” in such a structure and include other circuitized substrates and/or components electrically coupled thereto.

While there have been shown and described what are at present the preferred embodiments of the invention, it will be obvious to those skilled in the art that various changes and modifications may be made therein without departing from the scope of the invention as defined by the appended claims.

What is claimed is:

1. A method of making a circuitized substrate assembly, said method comprising:
providing first and second circuitized substrates, said first circuitized substrate having a first side and including at least one conductive thru-hole therein, said second circuitized substrate having a first side and including at least one conductive thru-hole therein;
orienting first and second circuitized substrates in a substantially planar orientation wherein said first side of said first circuitized substrate is positioned substantially contiguous to said first side of said second circuitized substrate;
positioning a third circuitized substrate having first and second conductive thru-holes therein onto both said first and second circuitized substrates such that said first conductive thru-hole of said third circuitized substrate is aligned with said at least one conductive thru-hole of said first circuitized substrate and said second conductive thru-hole of said third circuitized substrate is aligned with said at least one conductive thru-hole of said second circuitized substrate; and
bonding said first, second and third circuitized substrates together such that said first conductive thru-hole of said third circuitized substrate is electrically coupled to said at least one conductive thru-hole of said first circuitized substrate and said second conductive thru-hole of said third circuitized substrate is electrically coupled to said at least one conductive thru-hole of said second circuitized substrate, said first, second and third circuitized substrates forming a circuitized substrate assembly.

2. The method of claim 1 wherein bonding of said first, second and third circuitized substrates is accomplished using a lamination process.

3. The method of claim 2 wherein said lamination process is conducted at a temperature within the range of from about 180 degrees Celsius to about 220 degrees Celsius and at a pressure within the range of from about 300 PSI to about 1100 PSI.

4. The method of claim 1 further including positioning a first electrical component on said first circuitized substrate and a second electrical component on said second circuitized substrate such that said first and second electrical components are electrically coupled to said first and second circuitized substrates, respectively.

5. The method of claim 4 wherein said first, second and third circuitized substrates provide at least one circuit path to electrically coupled said first electrical component to said second electrical component.

6. The method of claim 5 further including providing at least one internal conductive plane within said first, second or third circuitized substrates prior to said bonding of said first, second and third substrates, said at least one internal conductive plane forming part of said at least one circuit path.

7. The method of claim 4 wherein said positioning of said first and second electrical components is accomplished using solder ball connections.

8. A method of making a circuitized substrate assembly, said method comprising:
providing first and second circuitized substrates, said first circuitized substrate having a first side and including at least one conductive thru-hole therein, said second circuitized substrate having a first side and including at least one conductive thru-hole therein;
orienting first and second circuitized substrates in a substantially planar orientation wherein said first side of said first circuitized substrate is positioned substantially contiguous to said first side of said second circuitized substrate;
providing third and fourth circuitized substrates, said third circuitized substrate having a first side and including at least one conductive thru-hole therein, said fourth circuitized substrate having a first side and including at least one conductive thru-hole therein, positioning said third and fourth circuitized substrates on said first and second circuitized substrates wherein said first side of said third circuitized substrate is positioned substantially contiguous to said first side of said fourth circuitized substrate and said at least one conductive thru-hole of said third circuitized substrate is aligned with said at least one conductive thru-hole of said first circuitized substrate and said at least one conductive thru-hole of said fourth circuitized substrate is aligned with said at least one conductive thru-hole of said second circuitized substrate; and
bonding said first, second, third and fourth circuitized substrates together such that said at least one conductive thru-hole of said third circuitized substrate is electrically coupled to said at least one conductive thru-hole of said first circuitized substrate and said at least one conductive thru-hole of said fourth circuitized substrate is electrically coupled to said at least one conductive thru-hole of said second circuitized substrate, said first, second, third and fourth circuitized substrates forming a circuitized substrate assembly.

9. The method of claim 8 wherein bonding of said first, second, third and fourth circuitized substrates is accomplished using a lamination process.

10. The method of claim 9 wherein said lamination process is conducted at a temperature within the range of from about 180 degrees Celsius to about 220 degrees Celsius and at a pressure within the range of from about 300 PSI to about 1100 PSI.

11. The method of claim 8 further including positioning a first electrical component on said first circuitized substrate and a second electrical component on said second circuitized substrate such that said first and second electrical components are electrically coupled to said first and second circuitized substrates, respectively.

12. The method of claim 11 wherein said first, second, third and fourth circuitized substrates provide at least one circuit path to electrically coupled said first electrical component to said second electrical component.

13. The method of claim 12 further including providing at least one internal conductive plane within said first, second, third or fourth circuitized substrates prior to said bonding of said first, second, third and fourth circuitized substrates, said at least one internal conductive plane forming part of said at least one circuit path.

14. The method of claim 11 wherein said positioning of said first and second electrical components is accomplished using solder ball connections.
